(19) United States
(12) Patent Application Publication
(10) Pub. No.: US 2024/0128218 A1
(43) Pub. Date: Apr. 18, 2024

(54) SEMICONDUCTOR PACKAGE AND MANUFACTURING METHOD THEREOF

(71) Applicant: Taiwan Semiconductor Manufacturing Company, Ltd., Hsinchu (TW)

(72) Inventors: Hung-Pin Chang, New Taipei City (TW); Wei-Cheng Wu, Hsinchu City (TW); Ming-Shih Yeh, Hsinchu County (TW); An-Jhih Su, Taoyuan City (TW); Der-Chyang Yeh, Hsin-Chu (TW)

(73) Assignee: Taiwan Semiconductor Manufacturing Company, Ltd., Hsinchu (TW)

(21) Appl. No.: 18/156,414

(22) Filed: Jan. 19, 2023

Related U.S. Application Data
(60) Provisional application No. 63/415,288, filed on Oct. 12, 2022.

(51) Int. Cl. H01L 23/00; H01L 23/31; H01L 23/498

(52) U.S. Cl. CPC H01L 24/13; H01L 23/3171; H01L 23/49816; H01L 24/05; H01L 24/06; H01L 24/11; H01L 24/16; H01L 24/24; H01L 2224/02233; H01L 2224/0401; H01L 2224/05022; H01L 2224/06132; H01L 2224/11849; H01L 2224/1191; H01L 2224/13021; H01L 2224/16147; H01L 2224/24146

(57) ABSTRACT

A semiconductor package includes a first semiconductor substrate, an array of conductive bumps, a second semiconductor substrate, and a spacing pattern. The first semiconductor substrate includes a pad region and an array of first pads disposed within the pad region. The array of conductive bumps is disposed on the array of first pads respectively. The second semiconductor substrate is disposed over the first semiconductor substrate and includes an array of second pads bonded to the array of conductive bumps respectively. The spacing pattern is disposed between the first semiconductor substrate and the second semiconductor substrate, wherein the spacing pattern is located at a periphery of the pad region.

### CROSS-REFERENCE TO RELATED APPLICATION

This application claims the priority benefit of U.S. provisional application Ser. No. 63/415,288, filed on Oct. 12, 2022. The entirety of the above-mentioned patent application is hereby incorporated by reference herein and made a part of this specification.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged. An example of such packaging systems is Package-on-Package (PoP) technology. In a PoP device, a top semiconductor package is stacked on top of a bottom semiconductor package to provide a high level of integration and component density. PoP technology generally enables production of semiconductor devices with enhanced functionalities and small footprints on a printed circuit board (PCB).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 7 illustrate cross sectional views of intermediate stages in the manufacturing of a semiconductor package according to some exemplary embodiments of the present disclosure.

FIG. 8 illustrates a cross sectional view of intermediate stages in the manufacturing of a semiconductor package according to another exemplary embodiment of the present disclosure.

FIG. 9 to FIG. 10 illustrate cross sectional views of intermediate stages in the manufacturing of a semiconductor package according to another exemplary embodiment of the present disclosure.

FIG. 11 to FIG. 13 illustrate top views of intermediate stages in the manufacturing of a semiconductor package according to some exemplary embodiments of the present disclosure.

FIG. 14 to FIG. 20 illustrate cross sectional views of intermediate stages in the manufacturing of a semiconductor package incorporating a semiconductor package according to some exemplary embodiments of the present disclosure.

FIG. 21 to FIG. 29 illustrate cross sectional views of intermediate stages in the manufacturing of a semiconductor package incorporating a semiconductor package according to some exemplary embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

This disclosure provides a semiconductor package with spacing pattern used in semiconductor devices applied to flip-chip assembly, wafer-level chip scale package (WLCSP), three-dimensional integrated circuit (3D-IC) stack, and/or any advanced package technology fields. Embodiments described herein relate to methods of forming semiconductor package with spacing pattern for use with semiconductor devices. In the following description, numerous specific details are set forth to provide a thorough understanding of the disclosure. However, one having an ordinary skill in the art will recognize that the disclosure can be practiced without these specific details. In some instances, well-known structures and processes have not been described in detail to avoid unnecessarily obscuring the disclosure. Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments. It should be appreciated that the following figures are not drawn to scale; rather, these figures are merely intended for illustration.

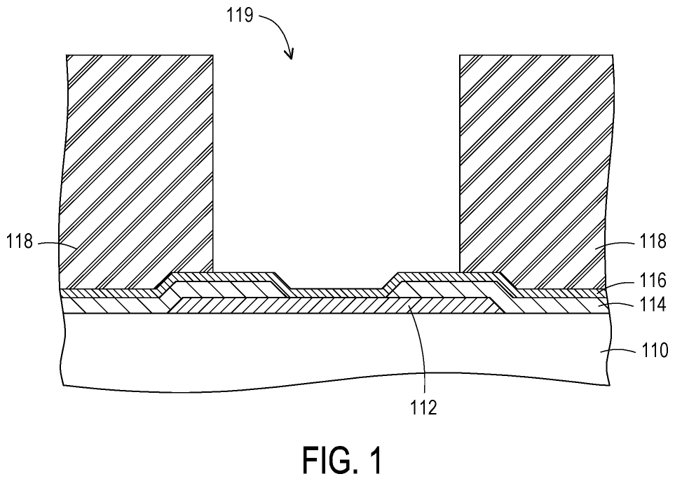

FIG. 1 to FIG. 7 illustrate cross sectional views of intermediate stages in the manufacturing of a semiconductor package according to some exemplary embodiments of the present disclosure. Referring firstly to FIG. 1, in some embodiments, a (first) semiconductor substrate 110 used for bump fabrication is employed in a semiconductor package fabrication, and integrated circuits may be formed therein and/or thereupon. The semiconductor substrate 110 is defined to mean any construction including semiconductor materials, including, but is not limited to, bulk silicon, a semiconductor wafer, a silicon-on-insulator (SOI) substrate, or a silicon germanium substrate. Other semiconductor materials including group III, group IV, and group V elements may also be used. The semiconductor substrate 110 may further include a plurality of isolation features (not shown), such as shallow trench isolation (STI) features or local oxidation of silicon (LOCOS) features. The isolation features may define and isolate the various microelectronic elements (not shown). Examples of the various microelectronic elements that may be formed in the semiconductor substrate 110 include transistors (e.g., metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), etc.), resistors, diodes, capacitors, inductors, fuses, or other suitable elements. Various processes are performed to form the various microelectronic elements including deposition, etching, implantation, photolithography, annealing, or other suitable processes. The microelectronic elements are interconnected to form the integrated circuit device, such as a logic device, memory device (e.g., static random access memory or SRAM), radio frequency (RF) device, input/output (I/O) device, system-on-chip (SoC) device, combinations thereof, or other suitable types of devices.

In some embodiments, the semiconductor substrate 110 further includes inter-layer dielectric layers and a metallization structure overlying the integrated circuits. The inter-layer dielectric layers in the metallization structure include low-k dielectric materials, undoped silicate glass (USG), silicon nitride, silicon oxynitride, or other commonly used materials. The dielectric constants (k value) of the low-k dielectric materials may be less than about 3.9, or less than about 2.8. Metal lines in the metallization structure may be formed of copper or copper alloys. One skilled in the art will realize the formation details of the metallization layers.

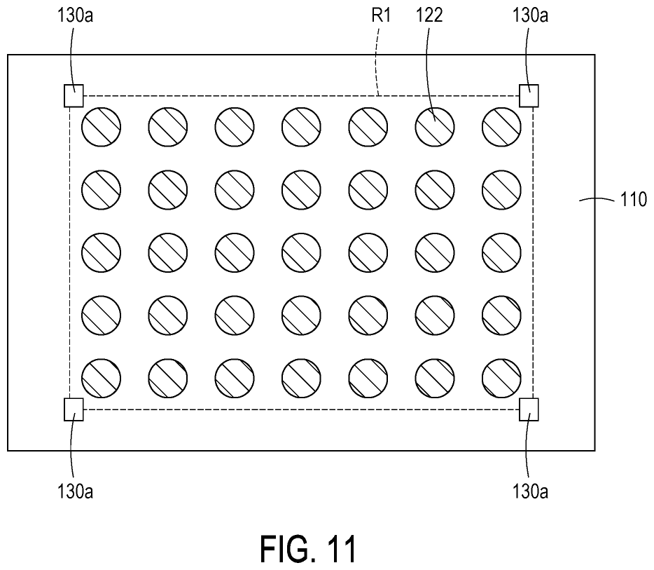

In accordance with some embodiments of the disclosure, the semiconductor substrate 110 may include a pad region (e.g., the pad region R1 shown in FIG. 11) and an array of first pads 112 disposed within the pad region R1. In the present embodiment, for purpose of simplicity, one first pad 112 is illustrated herein, but one of ordinary skills in the art should understand that the processes performed subsequentially should be applied over an array of first pads 112, such as the array of the first pads 112 shown in FIG. 11. In some embodiments, the first pad 112 may include a metallization layer formed over the inter-layer dielectric layers. The first pad 112 may be a portion of conductive routes and has an exposed surface treated by a planarization process, such as chemical mechanical polishing (CMP), if necessary. Suitable materials for the first pad 112 may include, but are not limited to, for example copper, aluminum, copper alloy, or other mobile conductive materials, although it may also be formed of, or include, other materials such as copper, silver, gold, nickel, tungsten, alloys thereof, and/or multi-layers thereof. The first pad 112 may be used in the bonding process to connect the integrated circuits in the respective device to external features. In some embodiments, a first passivation layer 114 is formed over the first semiconductor substrate 110, overlying the first pad 112. Using photolithography and etching processes, the first passivation layer 114 is patterned to form an opening at least revealing a part of the first pad 112. That is, the first passivation layer 114 covers the first semiconductor substrate 110 and revealing the array of first pads 112. In one embodiment, the first passivation layer 114 is formed of a non-organic material selected from undoped silicate glass (USG), silicon nitride, silicon oxynitride, silicon oxide, and combinations thereof. In another embodiment, the first passivation layer 114 is formed of a polymer layer, such as an epoxy, polyimide, benzocyclobutene (BCB), polybenzoxazole (PBO), and the like, although other relatively soft, often organic, dielectric materials can also be used.

In some embodiments, an under-bump-metallurgy (UBM) layer 116 may be formed on the first passivation layer 114, and electrically connected to the first pad 112. The UBM layer 116 is formed on the first passivation layer 114 and the revealed portion of the first pad 112. In an embodiment, the UBM layer 116 may further include a diffusion barrier layer and/or a seed layer. The diffusion barrier layer, also referred to as a glue layer, is formed to cover the sidewalls and the bottom of the opening of the first passivation layer 114. The diffusion barrier layer may be formed of titanium, although it may also be formed of other materials such as titanium nitride, tantalum, tantalum nitride, or the like. The formation methods include physical vapor deposition (PVD) or sputtering. The seed layer may be a copper seed layer formed on the diffusion barrier layer using PVD or sputtering. The seed layer may be formed of copper alloys that include silver, chromium, nickel, tin, gold, or combinations thereof. In one embodiment, the UBM layer 116 is a Cu/Ti layer. The diffusion barrier layer may have a thickness about 1000 Angstroms to about 2000 Angstroms, and the seed layer may have a thickness equal to about 3000 Angstroms to about 7000 Angstroms, although their thicknesses may also be greater or smaller. The dimensions recited throughout the description are merely examples, and will be scaled with the downscaling of integrated circuits.

Then, a mask layer 118 may be provided over the semiconductor substrate 110, e.g., the UBM layer 116 on the semiconductor substrate 110, and patterned with opening 119 for example, by exposure, development or etching, so that a portion of the UBM layer 116 is exposed for bump formation. The mask layer 118 may be a dry film, a photoresist film, or the like. In an embodiment, the mask layer 118 is a dry film, and may be formed of an organic material such as Ajinimoto buildup film (ABF). In alternative embodiments, the mask layer 118 is formed of a photo resist. The thickness of the mask layer 118 may be greater than about 5 μm, or even between about 10 μm and about 120 μm.

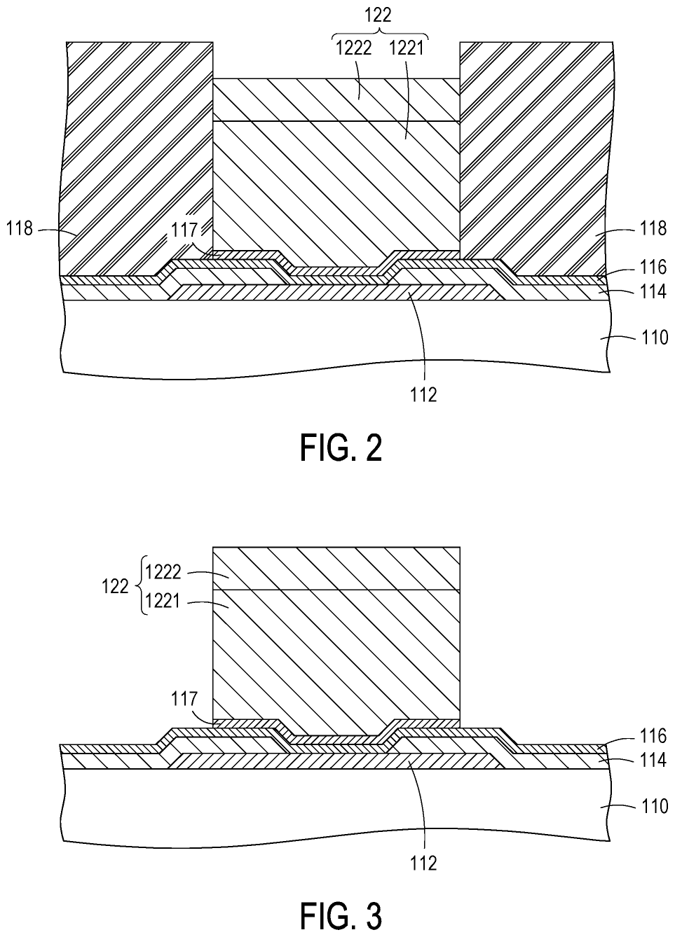

Referring to FIG. 2, then, in some embodiments, an array of conductive bumps 122 is formed on the array of first pads 112 respectively. In some embodiments, the conductive bumps 122 are micro bumps. However, in other embodiments, the conductive bumps 122 may include ball grid array (BGA) solder balls, controlled collapse chip connection (C4) bumps, Cu pillars, solder coated Cu micro pillars, or the like. The conductive bumps 122 may appear to have a rectangular, square, or a circular shape. A horizontal dimension (which may be a length, a width, or a diameter, depending on the shape of conductive bumps 122) may be between about 5 μm and about 30 μm, although different dimensional may be used. It is noted that one conductive bump 122 formed on a corresponding first pads 112 is illustrated herein, but one of ordinary skills in the art should understand that an array of conductive bumps such as the array of conductive bumps 122 may be formed on the array of first pads 112 respectively as shown in FIG. 11, for example. In some embodiments, the conductive bump 122 is formed over the UBM layer 116 within the opening 119 of the mask layer 118 by, for example, electro plating methods. In some embodiments, an optional metallization layer 117 is deposited in the opening 119 before the formation of the conductive bump 122. The optional metallization layer 117 may have a thickness less than 10 um. In some embodiments, the optional metallization layer 117 has a thickness about 1 μm to about 10 μm, for example about 4 μm to about 8 μm, although the thickness may be greater or smaller. The formation method of the metallization layer 117 may include electro plating methods. In one embodiment, the optional metallization layer 117 includes a copper layer, a copper alloy layer, a nickel layer, a nickel alloy layer, or combinations thereof. In some embodiments, the optional metallization layer 117 includes gold (Au), silver, palladium (Pd), indium (In), nickel-palladium-gold (NiPdAu), nickel-gold (NiAu), or other similar materials or alloy.

In some embodiments, the conductive bump 122 may include a metal pillar 1221 and a solder cap 1222. The metal pillar 1221 is formed within the opening 119. In an embodiment, the metal pillar 1221 may include a conductive material such as copper, aluminum, gold, nickel, palladium, the like, or a combination thereof. In one embodiment, a metal finish layer may be formed on the metal pillar 1221, for example, by plating. The metal finish layer may include different materials and layers, and may be used to prevent the oxidation and the diffusion of the metal pillar 1221 to/from the solder cap 1222. In an embodiment, the metal finish layer is formed of nickel, although other metals may be added. Alternatively, the metal finish layer may be formed of electroless nickel electroless palladium immersion gold (ENEPIG), which includes a nickel layer, a palladium layer on the nickel layer, and a gold layer on the palladium layer. The metal finish layer may be limited in the region directly over the metal pillar 1221, and is not formed on sidewalls of the metal pillar 1221. Alternatively, the metal finish layer is also formed on the sidewalls of the metal pillar 1221. Then, the solder cap 1222 may be formed over the metal pillar 1221, and may include a lead-free solder material containing, for example, Sn, SnAg, Sn—Pb, SnAgCu (with Cu weight percentage less than 0.3%), SnAgZn, SnZn, SnBi—In, Sn—In, Sn—Au, SnPb, SnCu, SnZnIn, or SnAgSb, etc., although the solder cap 1222 may also be formed of an eutectic solder material containing, for example, lead (Pb) and tin (Sn).

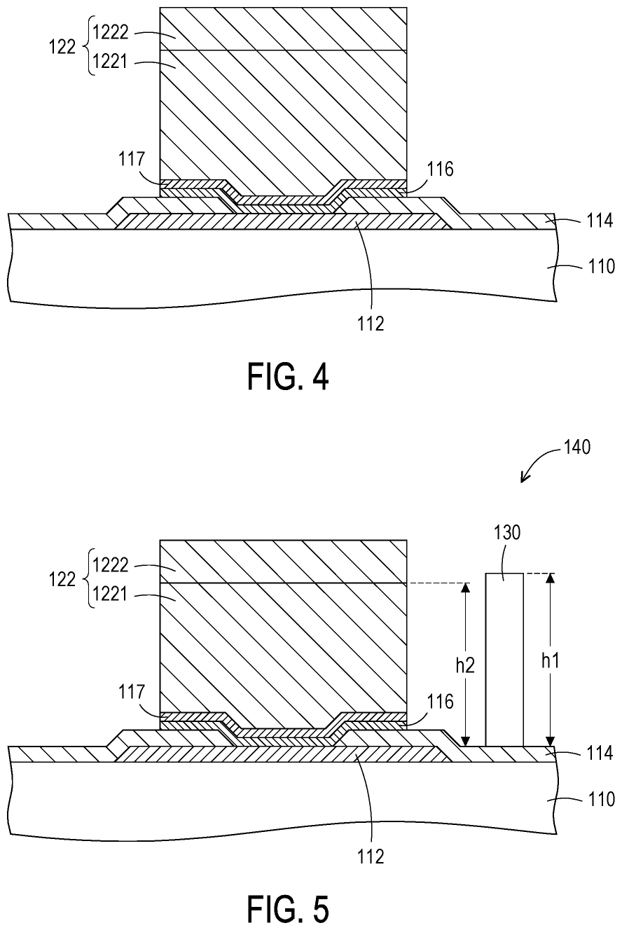

Next, the mask layer 118 is removed as shown in FIG. 3. In one embodiment, the mask layer 118 is a dry film, and it may be removed using an alkaline solution. If the mask layer 118 is formed of photoresist, it may be removed by a wet stripping process using acetone, n-methyl pyrrolidone (NMP), dimethyl sulfoxide (DMSO), aminoethoxy ethanol, and the like. Thus, the uncovered portions of the UBM layer 116 are exposed, and the formation of the conductive bump 122 is substantially done. In an embodiment, the thickness of the conductive bump 122 may be greater than 40 μm. In other embodiments, the thickness of the conductive bump 122 is about 40 μm to 70 μm, although the thickness may be greater or smaller. Next, as shown in FIG. 4, uncovered portions of the UBM layer 116 are removed to expose the underlying passivation layer 114 by etching methods, such as wet etching, dry etching or the like.

Then, a spacing pattern 130 is formed over the first semiconductor substrate 110. In some embodiments, the spacing pattern 130 is formed on the first passivation layer 114 after the conductive bump 122 is formed. The spacing pattern 130 are made of material different from a material of the conductive bump 122. For example, the spacing pattern 130 are made of a material which is substantially solid or has a melting or softening point considerably higher than the solder cap 1222 of the conductive bump 122. In other words, the spacing pattern 130 may be formed from materials of which the melting temperature is substantially greater than a melting temperature of the solder cap 1222, so that the spacing pattern 130 can remain in solid state during subsequent reflow process. In other words, the melting temperature of the spacing pattern 130 is substantially greater than a process temperature of the reflow process. For example, the melting temperature of the spacing pattern 130 is substantially equal to or greater than 200° C. In one embodiment, the melting temperature of the spacing pattern 130 is substantially equal to or greater than 250° C. The spacing pattern 130 may include metal material such as copper (Cu), nickel (Ni), gold (Au), cobalt (Co), etc., or polymer material such as polyimide (PI), benzocyclobutene (BCB), etc.

In one embodiment, the spacing pattern 130 may be formed from a photo-imageable polymer such as such as a photo-imageable epoxy (in particular a novolac epoxy) or other photo-imageable polyimide material. Other polymer families that can be prepared in photo-imageable form and are useful for this application include polyimide, polyarylene, parylene, benzocyclobutane, perfluorocyclobutane, silsequioxane, and silicone polymers. The polymer spacing pattern 130 may be initially deposited as a thick film on top of the passivation layer 114 after the conductive bump 122 is formed. The spacing pattern 130 is then exposed to UV light through a mask. A developing process is then effective at removing all of the polymer except where it was exposed to the UV light.

When cross sectioned in the plane of the spacing pattern 130, the spacing pattern 130 may take regular shapes such as a cylinder or a rectangle with widths in the range of 2 to 50 microns. Alternately, the spacing pattern 130 can have complex irregular cross sections which are designed to maximize the contact area of the spacing pattern 130 with the semiconductor substrate that is about to be mounted thereon. In some embodiments, the height h1 of the spacing pattern 130 is greater than the height of the metal pillar 1221 of the conductive bumps. In one embodiment, the height h1 of the spacing pattern 130 is greater than the height h2 of the metal pillar 1221 with respect to the same reference plane, e.g., a top surface of the passivation layer 114. After the spacing pattern 130 is formed, a semiconductor device 140 shown in FIG. 5 may be substantially formed.

The semiconductor device 140 may be a logic die (e.g., central processing unit, ASIC, FPGA, microcontroller, etc.), a memory die (e.g., a DRAM die, a Wide I/O die, a M-RAM die, a R-RAM die, a NAND die, an SRAM die, etc.), a memory cube (e.g. HBM, HMC, etc.), a high data rate transceiver die, a I/O interface die, a IPD die (e.g. integrated passives device), a power management die (e.g., a PMIC die), an RF die, a sensor die, an MEMS die, signal processing dies (e.g., a DSP die), a front-end die (e.g., an AFE dies), a monolithic 3D heterogeneous chiplet stacking die, the like, or a combination thereof.

FIG. 11 to FIG. 13 illustrate top views of intermediate stages in the manufacturing of a semiconductor package according to some exemplary embodiments of the present disclosure. Referring firstly to FIG. 5 and FIG. 11, in some embodiments, the spacing pattern 130 is located at a periphery of the pad region R1 where the array of the first pads 112 and the conductive bumps 122 are disposed. The spacing pattern 130 includes a plurality of spacers 130a at least disposed at a plurality of corners of the pad region R1 as it is shown in FIG. 11. In some embodiments, the spacers 130a may also be disposed in the central region of the pad region R1 among any two adjacent conductive bumps 122. The spacer 130a may be disposed at anywhere that is free of conductive bumps 122. When cross sectioned in the plane of the spacing pattern, each of the spacers 130a may take regular shapes such as a cylinder or a rectangle with widths in the range of 2 to 50 microns. Alternately, the spacing pattern 130 can have complex irregular cross sections which are designed to maximize the contact area of the spacers 130a with the semiconductor substrate that is about to be mounted thereon.

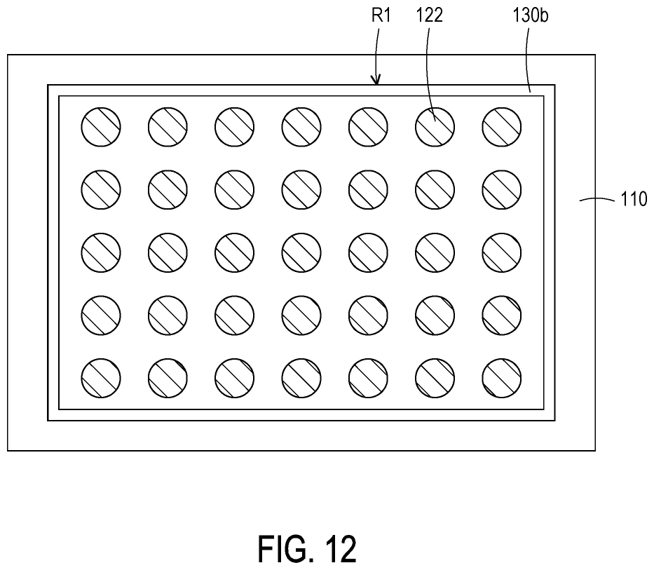

Referring now to FIG. 5 and FIG. 12, in some embodiments, the spacing pattern 130b may be in a continuous ring shape surrounding the periphery of the pad region R1 as it is shown in FIG. 12. The spacing pattern 130b may be a wall structure such as a ring or a square frame formed over the semiconductor substrate 110. The pads 112 and the conductive bumps 122 are disposed within the area surrounded by the spacing pattern 130b. Namely, the spacing pattern 130b defines the pad region R1 where the pads 112 and the conductive bumps 122 are disposed.

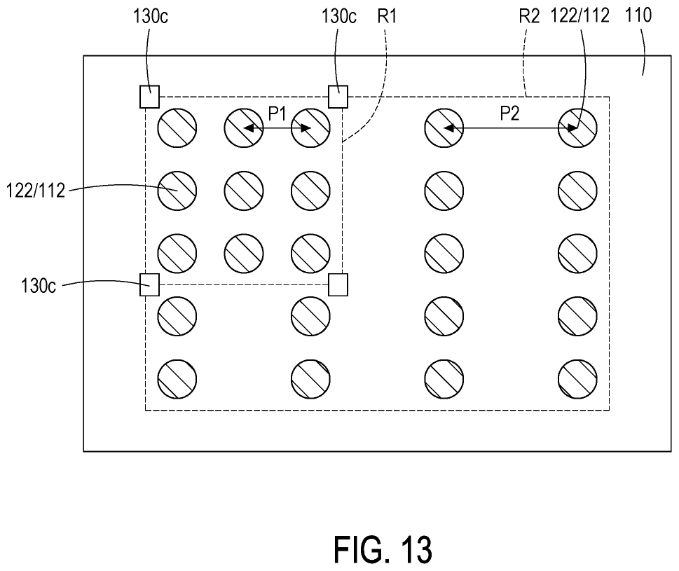

Referring now to FIG. 5 and FIG. 13, in some embodiments, the pad region may include a first region R1 and a second region R2, wherein a first pitch P1 between any adjacent two of the array of the conductive bumps 122 (and the corresponding pads 112) in the first region R1 is smaller than a second pitch P2 between any adjacent two of the array of the conductive bumps 122 (and the corresponding pads 112) in the second region R2. That is, the semiconductor substrate 110 includes a fine pitch region, i.e., the first region R1, and a primary pitch region, i.e., the second region R2. In one embodiment, the first pitch P1 in the first region may be substantially equal to or smaller than 10 μm. In some embodiments, the spacing pattern 130c is disposed at a periphery of the first region R1 as it is shown in FIG. 13. In the embodiment, the spacing pattern 130c is disposed at corners of the first region R1. However, in other embodiments, the spacing pattern 130c may also in a ring or square shape surrounding the first region R1.

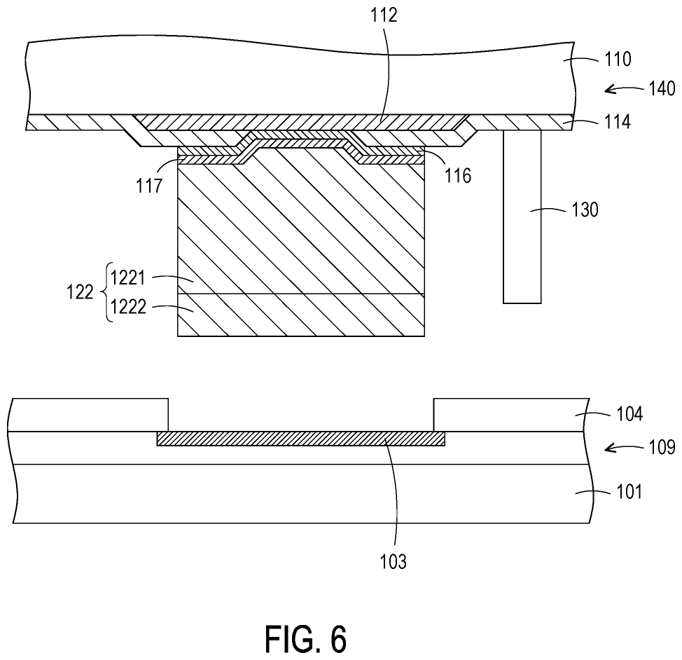

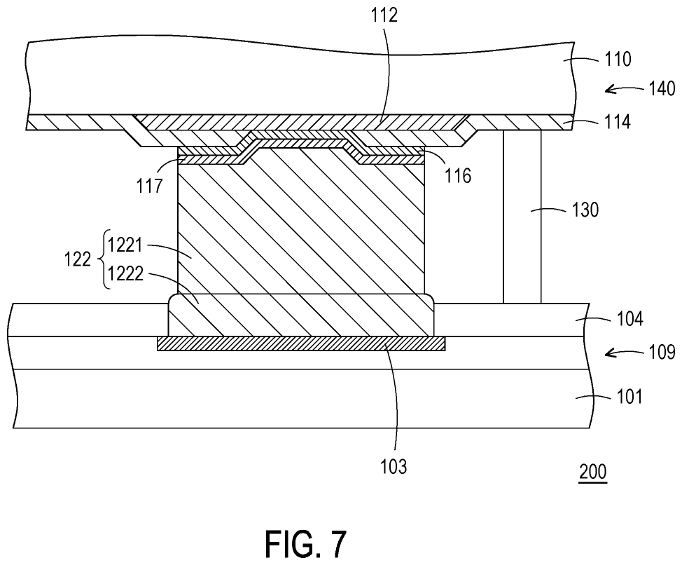

With now reference back to FIG. 6 and FIG. 7, then, a second semiconductor substrate 101 is provided and then bonded to the semiconductor device 140. In some embodiments, the second semiconductor substrate 101 includes an array of second pads 103 corresponding to the array of conductive bumps 122 on the first semiconductor substrate 110 respectively. For example, semiconductor substrate 101 may include silicon, doped or undoped, or an active layer of a semiconductor-on-insulator (SOI) substrate. The semiconductor substrate 101 may include other semiconductor material, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. Devices, such as transistors, diodes, capacitors, resistors, etc., may be formed in and/or on the semiconductor substrate 10 and may be interconnected by interconnect structures formed by, for example, metallization patterns in one or more dielectric layers on the semiconductor substrate 101 to form an integrated circuit. The interconnect structures are formed using damascene and/or dual-damascene process, in some embodiments.

In some embodiments, the semiconductor substrate 110 is a substrate of a semiconductor device 109. The semiconductor device 109 may be a logic die (e.g., central processing unit, mobile application processor, ASIC, GPU, FPGA, microcontroller, etc.), a memory die (e.g., dynamic random access memory (DRAM) die, a Wide I/O die, a M-RAM die, a R-RAM die, a NAND die, a static random access memory (SRAM) die, etc.), a memory cube (e.g. HBM, HMC, etc.), a high data rate transceiver die, a I/O interface die, a IPD die (e.g. integrated passives device), a power management die (e.g., power management integrated circuit (PMIC) die), a radio frequency (RF) die, a sensor die, a micro-electro-mechanical-system (MEMS) die, signal processing dies (e.g., digital signal processing (DSP) die), a front-end die (e.g., analog front-end (AFE) dies), a monolithic 3D heterogeneous chiplet stacking die, the like, or a combination thereof. In some embodiments, the semiconductor device 109 may be a logic die and the semiconductor device 140 may be a memory die, but the disclosure is not limited thereto. In some embodiments, the semiconductor substrate 110 is an interposer or a package substrate.

After the first semiconductor substrate 110 is placed over the second semiconductor substrate 101, the second semiconductor substrate 101 and the first semiconductor substrate 110 are bonded by performing a reflow process. The bonding process of the second semiconductor substrate 101 and the first semiconductor substrate 110 may be a die to die bonding process. However, in other embodiments, the bonding process may be performed at wafer level (e.g. chip on wafer or wafer on wafer), wherein there are multiple the semiconductor devices formed in a wafer and there are multiple semiconductor devices identical to the illustrated semiconductor devices 140, 109 are pre-bonded, and arranged as rows and columns on the wafer.

A reflow process is performed to cause the reflow of the solder cap 1222 and inter-diffusion of the solder and of the metals in at least one of the conductive bumps 122 and the pads 103. In accordance of some embodiment, a thermal compression bond (TCB) may be applied, which involves applying external pressure on the stacked devices during a thermal process to locally heat up the bonding interfaces for reducing the bonding time and the thermo-mechanical stress at the bonding joints due to a mismatch of coefficient of thermal expansion (CTE) among top circuit die, bottom circuit die, and bonding tool. In other embodiments, laser-assisted bonding (LAB) may also be applied to the reflow process.

In accordance with some embodiments of the disclosure, when the first semiconductor substrate 110 is placed over the second semiconductor substrate 101 with a pressing head, an external pressure is applied to the first semiconductor substrate 110, such that the spacing pattern 130 on the passivation layer 114 is pressed to be in contact with the passivation layer 104. Accordingly, the spacing pattern 130 is in contact with the first semiconductor substrate 110 and the second semiconductor substrate 101 during the reflow process. The spacing pattern 130 may act as spacers for maintaining a predetermined gap or spacing between the opposing substrates, e.g., the first semiconductor substrate 110 and the second semiconductor substrate 101.

When the solder cap 1222 is melting during the reflow process, the spacing pattern 130, with the height h1 higher than the height h2 of the metal pillar 1221 of the conductive bumps 122, is still in solid state to maintaining a predetermined gap or spacing between the substrates 110, 104, so as to avoid bridging between two adjacent conductive bumps 122 due to the first semiconductor substrate 110 being pressed to be too close to the second semiconductor substrate 101, which causes overflow of the melting solder. In other words, the configuration of the height h1 of the spacing pattern 130 greater than the height h2 of the metal pillar 1221 allows the melting solder cap 1222 to have enough space to be contained in the opening of the passivation layer 104 instead of being squeezed out (overflowing) and causing bridging between the adjacent conductive bumps 122.

Moreover, the spacing pattern 130 may act as a reference plane for horizontal calibration. That is, the top surface of the spacing pattern 130 defines a horizontal referencing plane. Accordingly, if the pressing head or the chuck table is deviated, when the first semiconductor substrate 110 is placed over the second semiconductor substrate 101, the top surface of the spacing pattern 130 is pressed to lean against the passivation layer 104 of the second semiconductor substrate 101 to calibrate the relative position between the substrates 110, 104 and make sure the gap or distance between the substrates 110, 104 is the same throughout the whole bonding area.

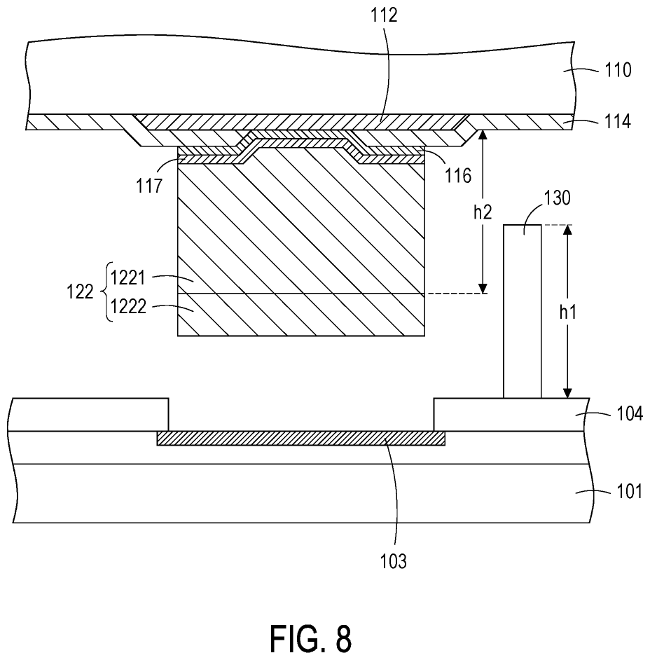

FIG. 8 illustrates a cross sectional view of intermediate stages in the manufacturing of a semiconductor package according to another exemplary embodiment of the present disclosure. In some embodiments, instead of being disposed on the first (upper) semiconductor substrate 110 with the conductive bumps 122, the spacing pattern 130 is disposed on the second (lower) semiconductor substrate 101. In one embodiment, the second semiconductor substrate 101 may include a second passivation layer 104 covering the second semiconductor substrate 101. In some embodiments, the second passivation layer 104 is formed over the second semiconductor substrate 101, overlying the second pad 103. Using photolithography and etching processes, the second passivation layer 104 is patterned to form an opening at least revealing a part of the second pad 103. In one embodiment, the second passivation layer 104 is formed of a non-organic material selected from undoped silicate glass (USG), silicon nitride, silicon oxynitride, silicon oxide, and combinations thereof. In another embodiment, the second passivation layer 104 is formed of a polymer layer, such as an epoxy, polyimide, benzocyclobutene (BCB), polybenzoxazole (PBO), and the like, although other relatively soft, often organic, dielectric materials can also be used. In one embodiment, the spacing pattern 130 is disposed on the passivation layer 104.

In some embodiments, the height of the spacing pattern 130 is substantially greater than a height of the metal pillar 1221. In one embodiment, the height h1 of the spacing pattern 130 from the top surface of the passivation layer 104 is greater than the height h2 of the metal pillar 1221 from the top surface of the passivation layer 114, so as to ensure that the melting solder cap 1222 would have enough space to be contained in the opening of the passivation layer 104 instead of being squeezed out (overflowing) and causing bridging between the adjacent conductive bumps 122.

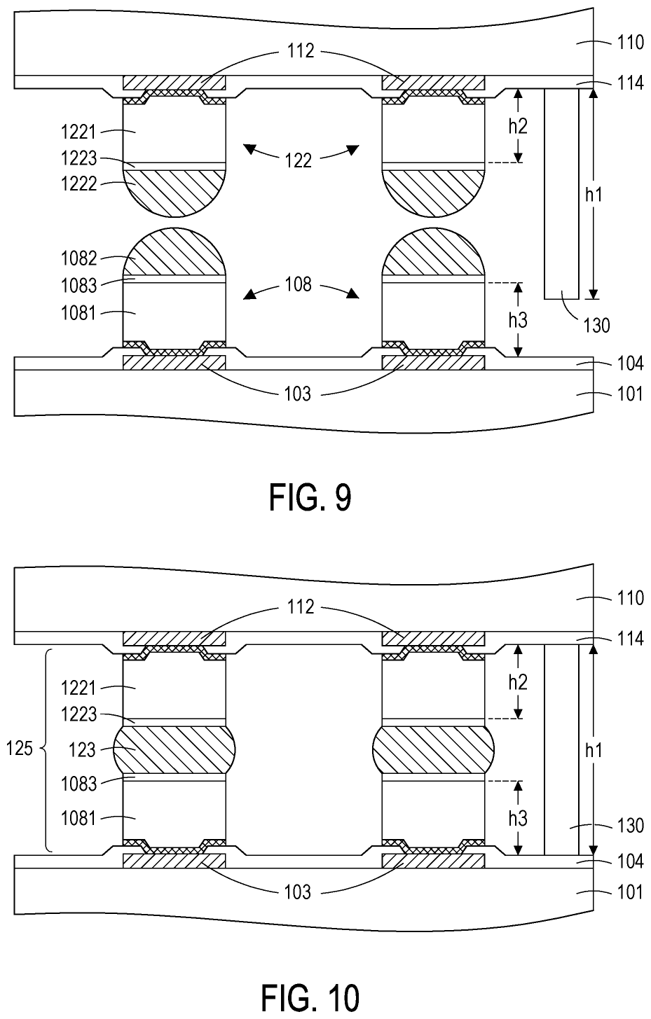

FIG. 9 to FIG. 10 illustrate cross sectional views of intermediate stages in the manufacturing of a semiconductor package according to another exemplary embodiment of the present disclosure. Referring to FIG. 9 and FIG. 10, in some embodiments, an array of conductive bumps 108 may also be formed on the array of the second pads 103 respectively. In some embodiments, the conductive bumps 108 may be micro bumps, which may include a metal pillar 1081 and a solder cap 1082 disposed over the metal pillar 1081. The conductive bumps 108 may appear to have a rectangular, square, or a circular shape. A horizontal dimension (which may be a length, a width, or a diameter, depending on the shape of conductive bumps 108 may be between about 5 μm and about 30 μm, although different dimensional may be used. Accordingly, the height h1 of the spacing pattern 130 from the top surface of the passivation layer 104 is greater than a sum of the height h2 of the metal pillar 1221 and the height h3 of the metal pillar 1081, i.e., h1>h2+h3, so as to ensure that the metal pillars 1221 and 1081 would not be pressed against each other and causes the melting solder caps 1222 and 1082 being squeezed and overflew and resulting in bridging between the adjacent conductive bumps 125.

In some embodiments, a metal finish layer 1083 may be disposed between the metal pillar 1081 and the solder cap 1082. Similarly, a metal finish layer 1223 may be disposed between the metal pillar 1221 and the solder cap 1222. The metal finish layers 1083, 1223 may be formed on the metal pillars 1081 and 1221 respectively, for example, by plating. The metal finish layers 1083, 1223 may include different materials and layers, and may be used to prevent the oxidation and the diffusion of the metal pillars 1081 and 1221 to/from the solder caps 108 and 1222. In some embodiment, the metal finish layers 1083, 1223 may be formed of nickel, although other metals may be added. Alternatively, the metal finish layers 1083, 1223 may be formed of electroless nickel electroless palladium immersion gold (ENEPIG), which includes a nickel layer, a palladium layer on the nickel layer, and a gold layer on the palladium layer. In one embodiment, the metal finish layer 36 may be limited in the region directly over the metal pillars 1081 and 1221, and not formed on sidewalls of the metal pillars 1081 and 1221. Alternatively, the metal finish layers 1083, 1223 may also be formed on the sidewalls of metal pillars 1081 and 1221 respectively.

Moreover, the spacing pattern 130 may act as a reference plane for horizontal calibration. That is, the top surface of the spacing pattern 130 defines a horizontal referencing plane. Accordingly, if the pressing head or the chuck table is deviated from a horizontal plane, when the first semiconductor substrate 110 is placed over the second semiconductor substrate 101, the top surface of the spacing pattern 130 would be pressed to lean against the passivation layer 114 to calibrate the relative position between the substrates 110, 101 and make sure the gap or distance between the substrates 110, 101 is the same throughout the whole bonding area.

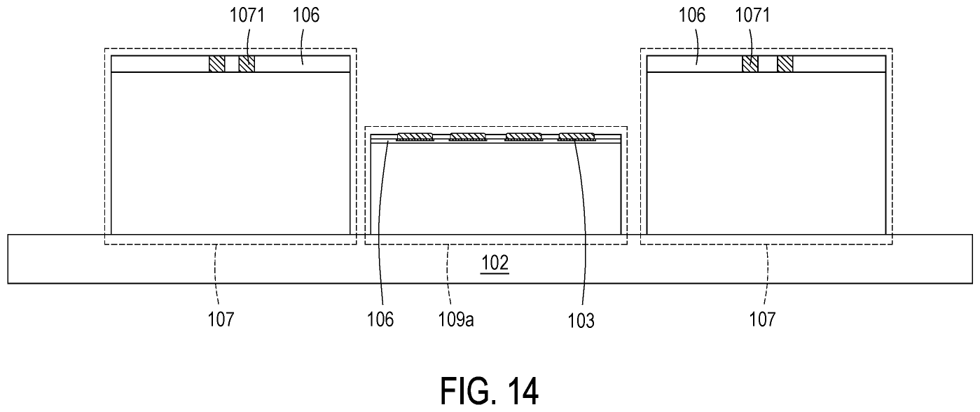

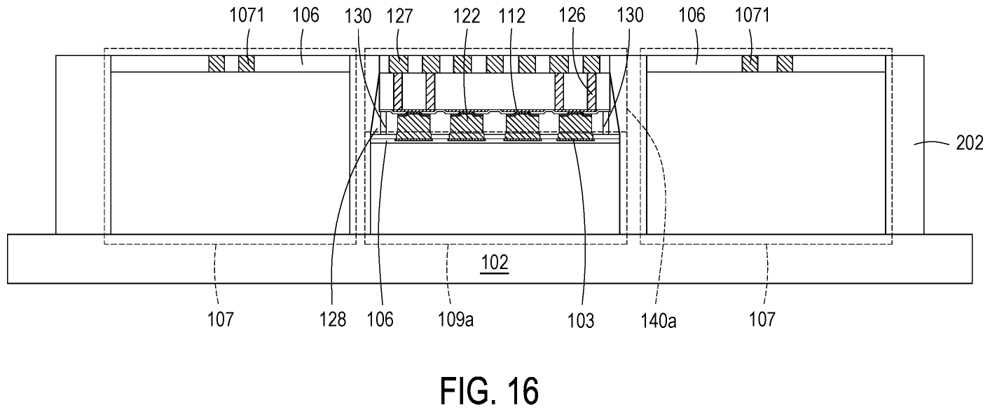

FIG. 14 to FIG. 20 illustrate cross sectional views of intermediate stages in the manufacturing of a semiconductor package incorporating a semiconductor package according to some exemplary embodiments of the present disclosure. In accordance with some embodiments of the disclosure, the structure described above may be applied to any semiconductor packages and manufacturing methods thereof that involve die to die, die to wafer, or wafer to wafer bonding, etc. The following embodiment is illustrated as an example of the spacing pattern 130 being used in a die-to-die bonding process, but the disclosure is not limited thereto.

Referring to FIG. 14, in some embodiments, a plurality of semiconductor devices 107, 109a are attached to a carrier substrate 102. In the embodiment, three semiconductor devices 107, 109a are adhered to the carrier substrate 102. In other embodiments, more or less semiconductor devices 107, 109a may be adhered to the carrier substrate 102. The carrier substrate 102 may be a glass carrier, a ceramic carrier, or the like. The carrier substrate 102 may be a wafer with a round top-view shape, such that multiple packages (e.g., in different package regions) can be formed on the carrier substrate 102 simultaneously. A release layer (not shown) may be formed on the carrier substrate 102. The release layer may be formed of a polymer-based material, which may be removed along with the carrier substrate 102 from the overlying structures that will be formed in subsequent steps. In some embodiments, the release layer is an epoxy-based thermal-release material, which loses its adhesive property when heated, such as a light-to-heat-conversion (LTHC) release coating. In other embodiments, the release layer may be an ultra-violet (UV) glue, which loses its adhesive property when exposed to UV lights. The release layer may be dispensed as a liquid and cured, may be a laminate film laminated onto the carrier substrate 102, or may be the like. The top surface of the release layer may be leveled and may have a high degree of coplanarity.

The semiconductor devices 107, 109a may each have a single function (e.g., a memory die), or may have multiple functions (e.g., a SoC). For example, the semiconductor devices may include a first die having a different function from each of a plurality of second dies. In an embodiment, the semiconductor devices include a first die, e.g., a system on a chip (SoC) die 109a, and a plurality of second dies, e.g., HBM dies 107. The HBM dies 107 shown in the embodiment of FIG. 14 through FIG. 20 may be higher capacity memories. As such, the HBM dies 107 may be thicker than the SoC die 109a. The semiconductor devices may be adhered to the carrier substrate 102 with an adhesive (not shown). The adhesive may be applied to a back-side of the semiconductor devices 107, 109a, such as to a back-side of the respective semiconductor wafer, or may be applied over the surface of the carrier substrate 102. The semiconductor devices 107, 109a may be dies initially formed in a wafer that are singulated, such as by sawing or dicing, and adhered to the carrier substrate 102 by the adhesive using, for example, a pick-and-place tool. The adhesive may be any suitable adhesive, epoxy, die attach film (DAF), or the like.

In some embodiments, each of the semiconductor devices 107, 109a may further include a dielectric layer 106 on the active side of the semiconductor devices 107, 109a. The dielectric layer 106 laterally encapsulates the pads 103. In some embodiments, the dielectric layer 106 may be a polymer such as polybenzoxazole (PBO), polyimide, BCB, or the like; a nitride such as silicon nitride or the like; an oxide such as silicon oxide, PhosphoSilicate Glass (PSG), BoroSilicate Glass (BSG), Boron-doped PhosphoSilicate Glass (BPSG), or the like; the like, or a combination thereof, and may be formed, for example, by spin coating, lamination, CVD, or the like.

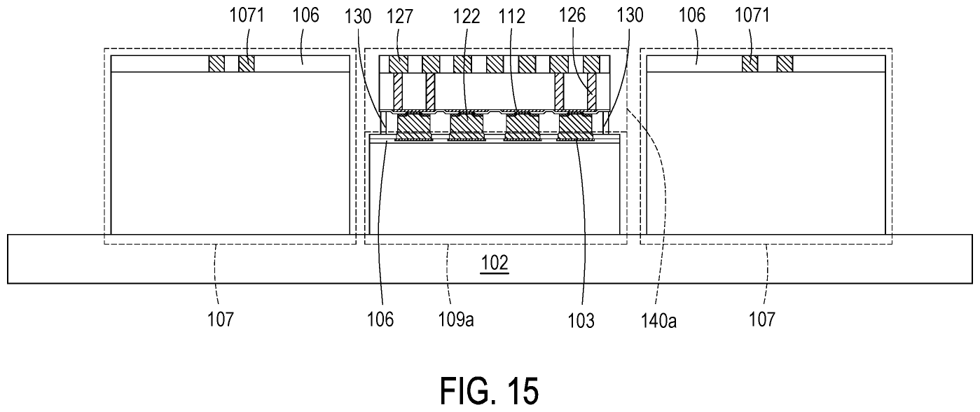

Referring to FIG. 15, a semiconductor device 140a may be place over the semiconductor device 109a, and bonded to the semiconductor device 109a by a reflow process. In one embodiment, the semiconductor device 140a may be a passive device that is bonded to the SoC die 109a. That is, the passive device 140a is disposed over the SoC die 109a and between the HBM dies 107. In some embodiments, the semiconductor device 140a is an active device, such as a logic device, memory device or others. In some embodiments, the conductive bumps 122 may be used to connect the pads 112 of the first semiconductor device 140a directly to the pads 103 of the second semiconductor device 109a. The spacing pattern 130 as described in the previous embodiments may be disposed on the first semiconductor device 140a or the second semiconductor device 109a. As such, after the bonding process, the spacing pattern 130 is between and in physical contact with the first semiconductor device 140a and the second semiconductor device 109a for maintaining a predetermined gap or spacing between the first semiconductor device 140a and the second semiconductor device 109a during the reflow process, so as to avoid bridging between two adjacent conductive bumps 122.

In some embodiments, the semiconductor device 140a may further include through silicon vias (TSVs) 126 and connectors 127. The TSVs 126 extend through the substrate of the semiconductor device 140a, and connect the connectors 127 to the pads 112. It should be appreciated that each one of the pads 112 may not be connected to a respective connector 127. For example, some of the pads 112 may be connected to the features of the semiconductor device 140a, and others of the pads 112 may be connected to respective connectors 127 through the TSVs 126. Further, some of the pads 112 may be connected to both the features of the semiconductor device 140a and respective connectors 127.

Referring to 16, then, an underfill 128 may optionally be filled into the gap between the first semiconductor device 140a and the second semiconductor device 109a and around the conductive bumps 122. The underfill 128 may be a molding compound, an epoxy, a molding underfill (MUF), a resin, or the like. The underfill 128 provides structural support for the semiconductor device 140a, and may be dispensed using capillary forces after the semiconductor device 140a is bonded to the semiconductor device 109a. Other encapsulating processes may be used, such as lamination, compression molding, transfer molding, or the like. A curing step may then be performed to cure and solidify the underfill 128.

Then, an encapsulant 202 at least encapsulates one of the semiconductor devices 140a, 107, 109a. In the embodiment, the encapsulant 202 encapsulates all of the semiconductor devices 140a, 107, and 109a. The encapsulant 202 may be a molding compound, epoxy, or the like, and may be applied by compression molding, transfer molding, or the like. After curing, the encapsulant 202 may undergo a planarization process to expose the connectors 1071 of the semiconductor devices 107 and the connectors 127 of the semiconductor device 140a. In some embodiments, the connectors 1071, 127 may be conductive pillars (for example, including a metal such as copper, aluminum, tungsten, nickel, or alloys thereof), and are mechanically and electrically connected to the interconnects of the semiconductor devices 107 and 140a respectively. The connectors 1071, 127 may be formed by, for example, plating, or the like. The planarization process may be a CMP, a grinding process, or the like. After planarization, top surfaces of the encapsulant 202, the semiconductor devices 107, and 140a are level with one another.

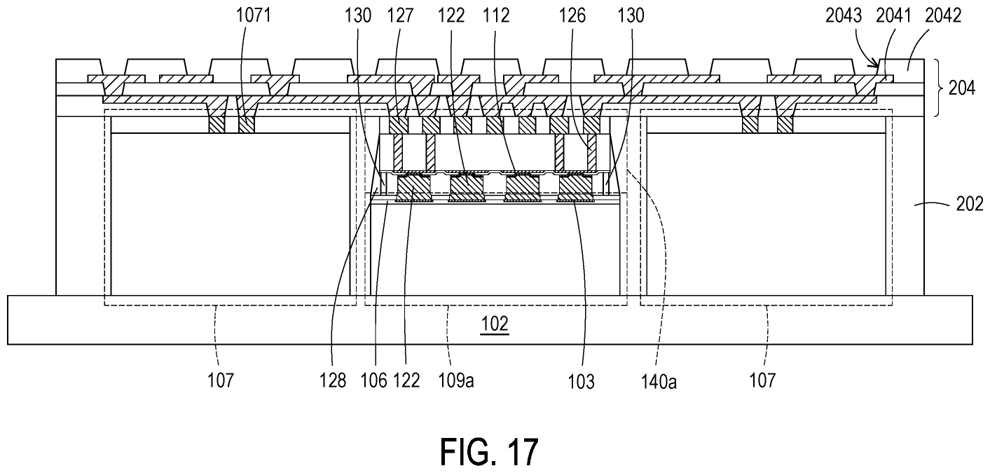

Referring to FIG. 17, then, a redistribution structure 204 is formed over encapsulant 202 and the semiconductor devices 107, and 140a. The redistribution structure 204 may be used to fan out electrical connections from the semiconductor devices 107, 109a and/or semiconductor device 140a. The redistribution structure 204 is connected to the connectors of the semiconductor devices 107 and the semiconductor device 140a. In some embodiments, the redistribution structure 204 is electrically connected to the semiconductor device 109a through the semiconductor device 140a. Openings may be formed in the top dielectric or passivation layer of the redistribution structure 204, exposing some or all of the top metal layer of the redistribution structure 204.

In some embodiments, a redistribution structure 204 is formed over and electrically connected to the semiconductor devices 107, 109a and 140a. In some embodiments, the redistribution structure 204 may be formed by, for example, depositing conductive layers, patterning the conductive layers to form redistribution circuits 2041, partially covering the redistribution circuits 2041 and filling the gaps between the redistribution circuits 2041 with dielectric layers 2042, etc. The material of the redistribution circuits 2041 may include a metal or a metal alloy including aluminum, copper, tungsten, and/or alloys thereof. The dielectric layers 2042 may be formed of dielectric materials such as oxides, nitrides, carbides, carbon nitrides, combinations thereof, and/or multi-layers thereof. The redistribution circuits 2041 are formed in the dielectric layers 2042 and electrically connected to the connectors 127, 1071. In addition, an Under Bump Metallurgy (UBM) layer may be formed on the redistribution structure 204 by sputtering, evaporation, or electroless plating, etc.

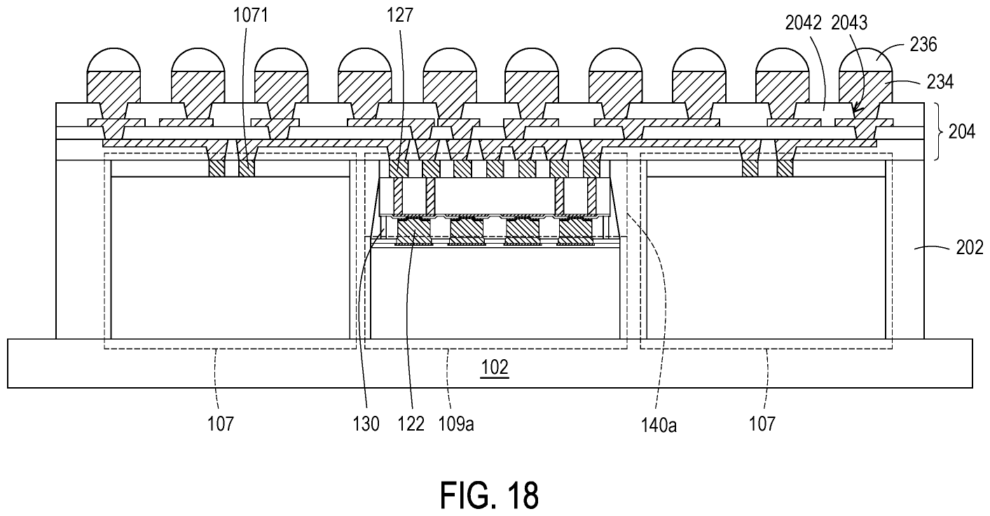

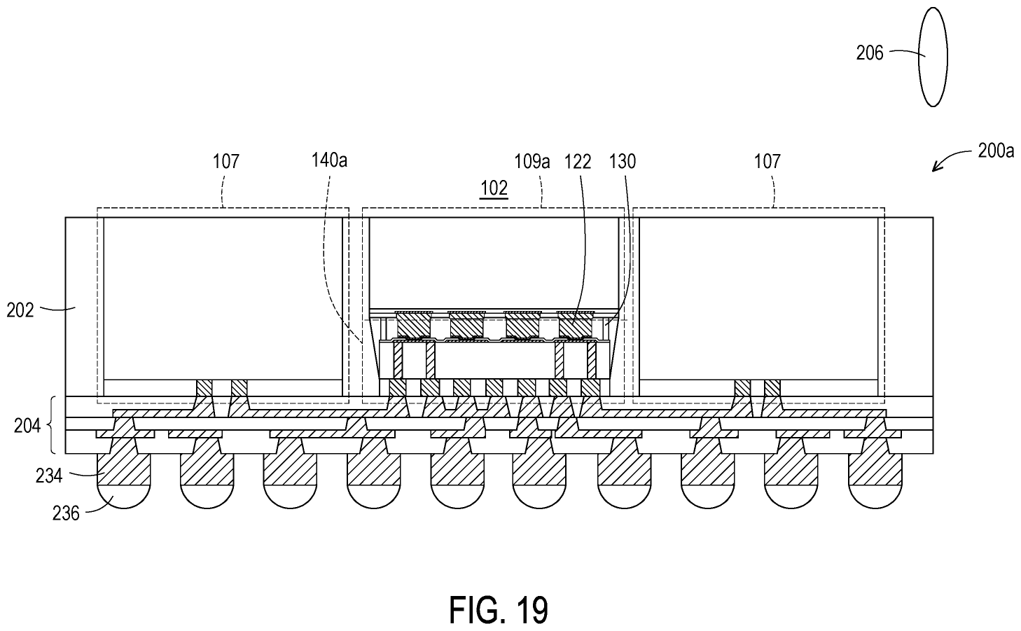

Referring to FIG. 18 and FIG. 19, the bumps 234 are formed through the openings 2043 in the dielectric layer 2042 of the redistribution structure 204. A plurality of conductive connectors 236 are formed over the bumps 234 respectively. In the embodiment, the bumps 234 are configured to contact metallization patterns in the redistribution structure 204. The bumps 234 may be metal pillars, controlled collapse chip connection (C4) bumps, micro bumps, electroless nickel-electroless palladium-immersion gold technique (ENEPIG) formed bumps, ball grid array (BGA) bumps, or the like. In an embodiment, the bumps 234 are C4 bumps. The bumps 234 may be formed by a sputtering, printing, electro plating, electroless plating, CVD, or the like. The bumps 234 may be solder free and have substantially vertical sidewalls. In some embodiments, a metal cap layer (not shown) is formed on the top of the bumps 234. The metal cap layer may include nickel, tin, tin-lead, gold, silver, palladium, indium, nickel-palladium-gold, nickel-gold, the like, or a combination thereof and may be formed by a plating process.

Further in FIG. 18, conductive connectors 236 are formed on the bumps 234. The conductive connectors 236 may be formed from a conductive material such as solder, copper, aluminum, gold, nickel, silver, palladium, tin, the like, or a combination thereof. In some embodiments, the conductive connectors 236 are formed by initially forming a layer of solder through methods such as evaporation, electroplating, printing, solder transfer, ball placement, or the like. Once a layer of solder has been formed on the structure, a reflow may be performed in order to shape the conductive connectors 236 into desired bump shapes.

Referring to FIG. 18 and FIG. 19, a carrier substrate de-bonding is performed to detach (de-bond) the carrier substrate 102 from the back sides of semiconductor devices 107, 109a and the back surface of the encapsulant 202. De-bonding may be accomplished through, e.g., use of the release layer (not shown). In accordance with some embodiments, use of the release layer includes projecting a light such as a laser light or an UV light on the release layer so that the release layer decomposes under the heat of the light and the carrier substrate 102 can be removed. Then, a singulation process is performed by sawing 206 along scribe line regions. The singulated structure is a semiconductor package 200a. The semiconductor package 200a may also be referred to as a multi-stack die package.

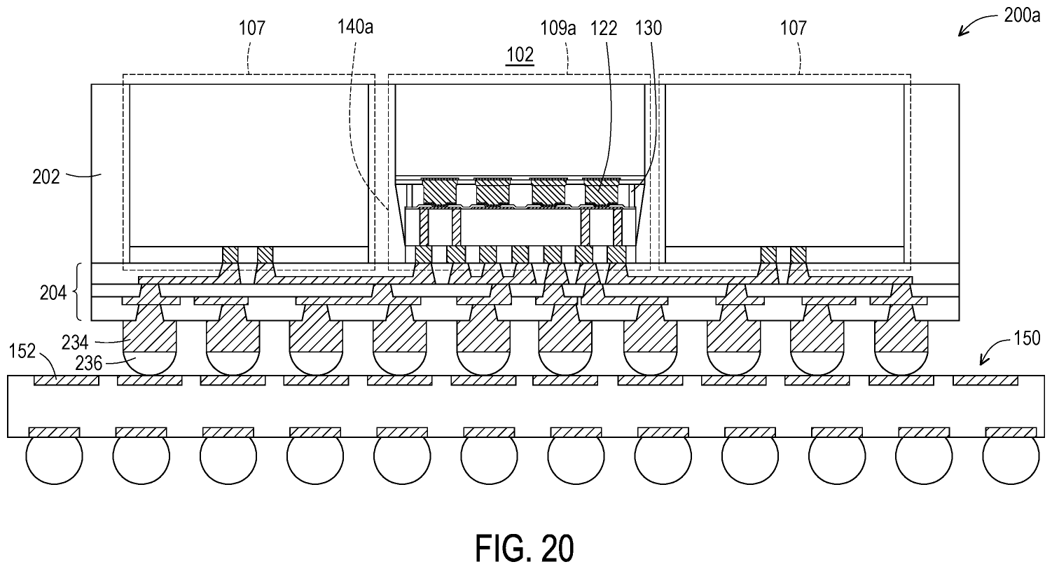

With now reference to FIG. 20, the semiconductor package 200a may then be bonded to a package substrate 150 to form a resulting package structure. The substrate 150 may be referred to as a package substrate 150, and may be, e.g., a printed circuit board (PCB) or the like, and may be connected to the semiconductor package 200a using the conductive connectors 236. The package substrate 150 may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the package substrate 150 may be a SOI substrate. Generally, an SOI substrate includes a layer of a semiconductor material such as epitaxial silicon, germanium, silicon germanium, SOI, SGOI, or combinations thereof. The package substrate 150 is, in one alternative embodiment, based on an insulating core such as a fiberglass reinforced resin core. One example core material is fiberglass resin such as FR4. Alternatives for the core material include bismaleimide-triazine BT resin, or alternatively, other PCB materials or films. Build up films such as ABF or other laminates may be used for package substrate 150.

The package substrate 150 may include active and passive devices (not shown). As one of ordinary skill in the art will recognize, a wide variety of devices such as transistors, capacitors, resistors, combinations of these, and the like may be used to generate the structural and functional requirements of the design for the resulting package structure. The devices may be formed using any suitable methods.

The package substrate 150 may also include metallization layers and vias (not shown), and bond pads 152 over the metallization layers and vias. The metallization layers may be formed over the active and passive devices and are designed to connect the various devices to form functional circuitry. The metallization layers may be formed of alternating layers of dielectric (e.g., low-k dielectric material) and conductive material (e.g., copper) with vias interconnecting the layers of conductive material and may be formed through any suitable process (such as deposition, damascene, dual damascene, or the like). In some embodiments, the package substrate 150 is substantially free of active and passive devices.

In some embodiments, the conductive connectors 236 are reflowed and bonded to the bond pads 152 of the package substrate 150. In one embodiment, the spacing pattern described above may be disposed on the semiconductor package 200a or the package substrate 150 for maintaining a predetermined gap or spacing between the semiconductor package 200a and the package substrate 150 during the reflow process, so as to avoid bridging between two adjacent conductive connectors 236.

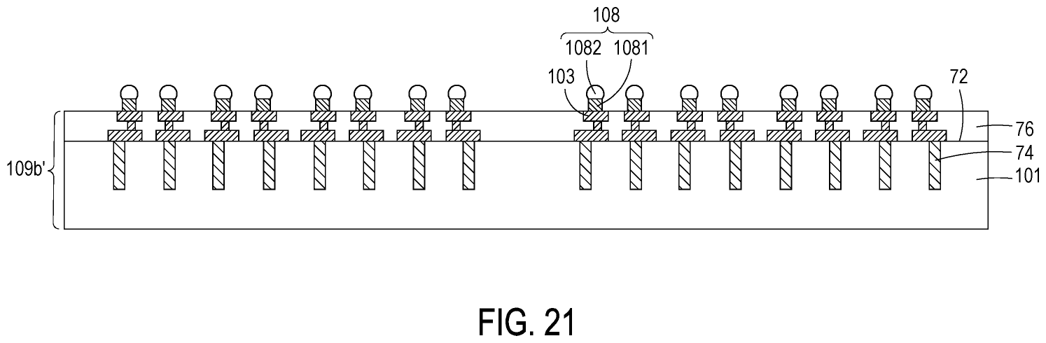

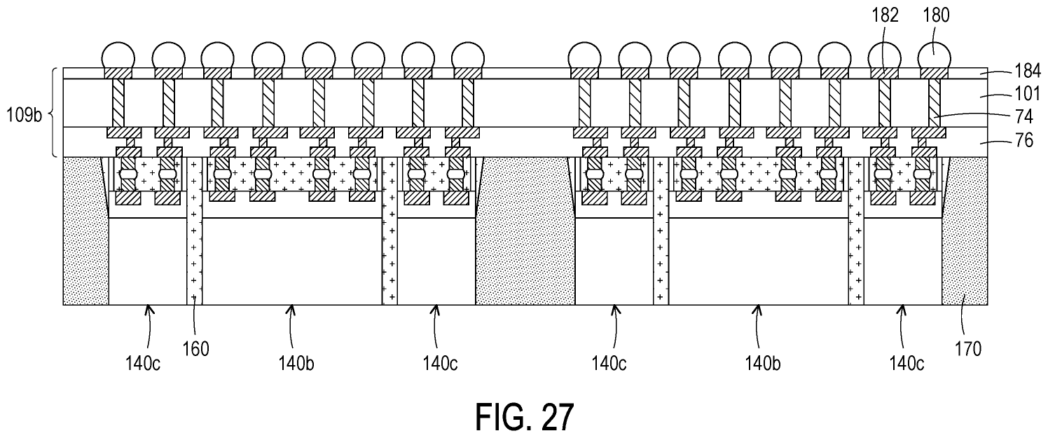

FIG. 21 to FIG. 29 illustrate cross sectional views of intermediate stages in the manufacturing of a semiconductor package incorporating a semiconductor package according to some exemplary embodiments of the present disclosure. In accordance with some embodiments of the disclosure, another embodiment is illustrated as an example of the spacing pattern being used in a die to wafer bonding process, but the disclosure is not limited thereto.

Referring to FIG. 21, a semiconductor device 109b′ is provided. In some embodiments, the semiconductor device 109b′ may be an intermediate structure of an interposer or another die. In the embodiment, the semiconductor device 109b′ includes a semiconductor substrate 101, which can be a wafer. The semiconductor substrate 101 may include a bulk semiconductor substrate, SOI substrate, multi-layered semiconductor substrate, or the like. The material of the semiconductor substrate 101 may be silicon, germanium, a compound semiconductor including silicon germanium, silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 101 may be doped or undoped. Devices, such as transistors, capacitors, resistors, diodes, and the like, may be formed in and/or on a first surface 72, which may also be referred to as an active surface, of the semiconductor substrate 101. In embodiments where the semiconductor device 109b′ is an intermediate structure of an interposer, the semiconductor device 109b′ may generally not include active devices therein, although the interposer may include passive devices formed in and/or on the first surface 72.

Through-vias (TVs) 74 are formed in the semiconductor substrate 101. The TVs 74 are also sometimes referred to as through-substrate vias or through-silicon vias when the semiconductor substrate 101 is a silicon substrate. The TVs 74 may be formed by forming recesses in the semiconductor substrate 101 by, for example, etching, milling, laser techniques, a combination thereof, and/or the like. A thin dielectric material may be formed in the recesses, such as by using an oxidation technique. A thin barrier layer may be conformally deposited over the front side of the semiconductor substrate 101 and in the openings, such as by CVD, ALD, PVD, thermal oxidation, a combination thereof, and/or the like. The barrier layer may comprise a nitride or an oxynitride, such as titanium nitride, titanium oxynitride, tantalum nitride, tantalum oxynitride, tungsten nitride, a combination thereof, and/or the like. A conductive material may be deposited over the thin barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer is removed from the front side of the substrate 70 by, for example, CMP. Thus, the TVs 74 may include a conductive material and a thin barrier layer between the conductive material and the semiconductor substrate 101.

In some embodiments, a redistribution structure 76 is formed over the first surface 72 of the semiconductor substrate 101, and is used to electrically connect the integrated circuit devices, if any, and/or TVs 74 together and/or to external devices. The redistribution structure 76 may include one or more dielectric layer(s) and respective metallization pattern(s) in the dielectric layer(s). The metallization patterns may comprise vias and/or traces to interconnect any devices and/or TVs 74 together and/or to an external device. The metallization patterns are sometimes referred to as Redistribution Lines (RDL). The dielectric layers may comprise silicon oxide, silicon nitride, silicon carbide, silicon oxynitride, low-K dielectric material, such as PSG, BPSG, FSG, SiOxCy, Spin-On-Glass, Spin-On-Polymers, silicon carbon material, compounds thereof, composites thereof, combinations thereof, or the like. The dielectric layers may be deposited by any suitable method known in the art, such as spinning, CVD, PECVD, HDP-CVD, or the like. A metallization pattern may be formed in the dielectric layer, for example, by using photolithography techniques to deposit and pattern a photoresist material on the dielectric layer to expose portions of the dielectric layer that are to become the metallization pattern. An etch process, such as an anisotropic dry etch process, may be used to create recesses and/or openings in the dielectric layer corresponding to the exposed portions of the dielectric layer. The recesses and/or openings may be lined with a diffusion barrier layer and filled with a conductive material. The diffusion barrier layer may comprise one or more layers of TaN, Ta, TiN, Ti, CoW, or the like, deposited by ALD, or the like, and the conductive material may comprise copper, aluminum, tungsten, silver, and combinations thereof, or the like, deposited by CVD, PVC, or the like. Any excessive diffusion barrier layer and/or conductive material on the dielectric layer may be removed, such as by using a CMP.

The conductive bumps 108 are formed at the top surface of the redistribution structure 76 on conductive pads. In some embodiments, the conductive pads include under bump metallurgies (UBMs). In the illustrated embodiment, the pads are formed in openings of the dielectric layers of the redistribution structure 76. In another embodiment, the pads (UBMs) can extend through an opening of a dielectric layer of the redistribution structure 76 and also extend across the top surface of the redistribution structure 76.

In some embodiments, the conductive bumps 108 may include a metal pillar 1081 and a solder cap 1082, which may be a solder cap, over the metal pillar. In some embodiments, the conductive bumps 108 are referred to as micro bumps 108. In some embodiments, the metal pillar 1081 include a conductive material such as copper, aluminum, gold, nickel, palladium, the like, or a combination thereof and may be formed by sputtering, printing, electro plating, electroless plating, CVD, or the like. The metal pillar 1081 may be solder free and have substantially vertical sidewalls. In some embodiments, the solder cap 1082 is formed on the top of the metal pillar 1081. The solder cap 1082 may include a lead-free solder material containing, for example, Sn, SnAg, Sn—Pb, SnAgCu (with Cu weight percentage less than 0.3%), SnAgZn, SnZn, SnBi—In, Sn—In, Sn—Au, SnPb, SnCu, SnZnIn, or SnAgSb, etc., although the solder cap 1222 may also be formed of an eutectic solder material containing, for example, lead (Pb) and tin (Sn), the like, or a combination thereof and may be formed by a plating process.

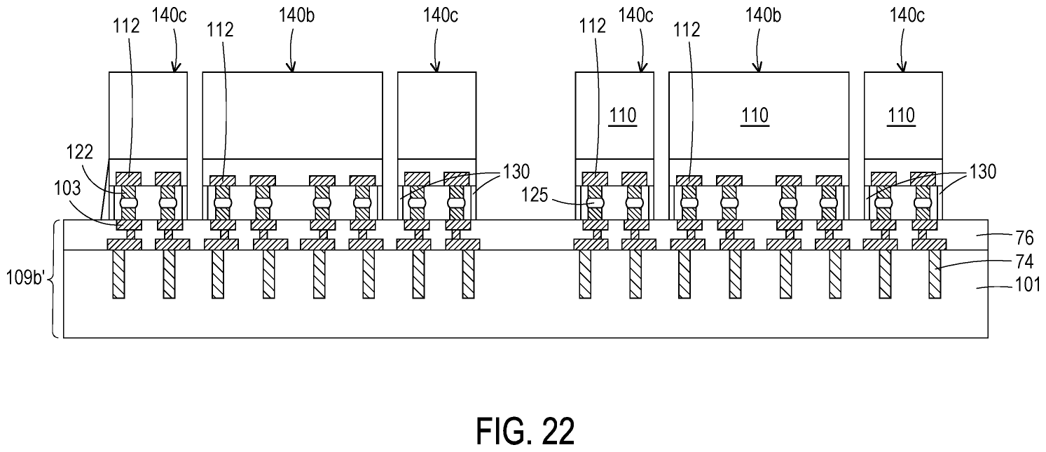

Referring to FIG. 22, a plurality of semiconductor devices 140a, 140b are bonded to the semiconductor substrate 101, for example, through flip-chip bonding by way of the conductive bumps 108 and the conductive bumps 122 on the semiconductor devices 140a, 140b to form conductive joints 125. The conductive bumps 122 may be similar to the conductive bumps 108 and the description is not repeated herein. The semiconductor devices 140a, 140b may be placed on the conductive bumps 108 using, for example, a pick-and-place tool. In some embodiments, the semiconductor devices 140a, 140b are bonded to the semiconductor device 109 by a reflow process. The spacing pattern 130 as described in the previous embodiments may be disposed on the semiconductor substrate 101 or the semiconductor devices 140a, 140b. As such, after the bonding process, the spacing pattern 130 is between and in physical contact with the semiconductor substrate 101 or the semiconductor devices 140a, 140b for maintaining a predetermined gap or spacing therebetween during the reflow process, so as to avoid bridging between two adjacent conductive joints 125. It is noted that the bonding structures (e.g., conductive joints 125) for bonding the semiconductor devices 140a, 140b and the semiconductor device 109b′ in the present embodiment are merely for illustration, the types and the formats of the bonding structures between the semiconductor devices 140a, 140b and the semiconductor device 109b′ are not limited thereto.

In some embodiments, the semiconductor devices 140a may include one or more memory dies, such as a stack of memory dies (e.g., DRAM dies, SRAM dies, High-Bandwidth Memory (HBM) dies, Hybrid Memory Cubes (HMC) dies, or the like). In the stack of memory dies embodiments, the semiconductor devices 140a can include both memory dies and a memory controller, such as, for example, a stack of four or eight memory dies with a memory controller. Also, in some embodiments, the semiconductor devices 140a may be different sizes (e.g., different heights and/or surface areas), and in other embodiments, the semiconductor devices 140a may be the same size (e.g., same heights and/or surface areas).

In some embodiments, the semiconductor devices 140b may include one or more logic dies (e.g., central processing unit, graphics processing unit, system-on-a-chip, field-programmable gate array (FPGA), microcontroller, or the like), memory dies (e.g., dynamic random access memory (DRAM) die, static random access memory (SRAM) die, or the like), power management dies (e.g., power management integrated circuit (PMIC) die), radio frequency (RF) dies, sensor dies, micro-electro-mechanical-system (MEMS) dies, signal processing dies (e.g., digital signal processing (DSP) die), front-end dies (e.g., analog front-end (AFE) dies), the like, or a combination thereof. The conductive joints 125 electrically couple the circuits in the semiconductor devices 140a, 140b through the conductive joints 125 respectively, to redistribution structure 76 and TVs 74 in the semiconductor device 109.

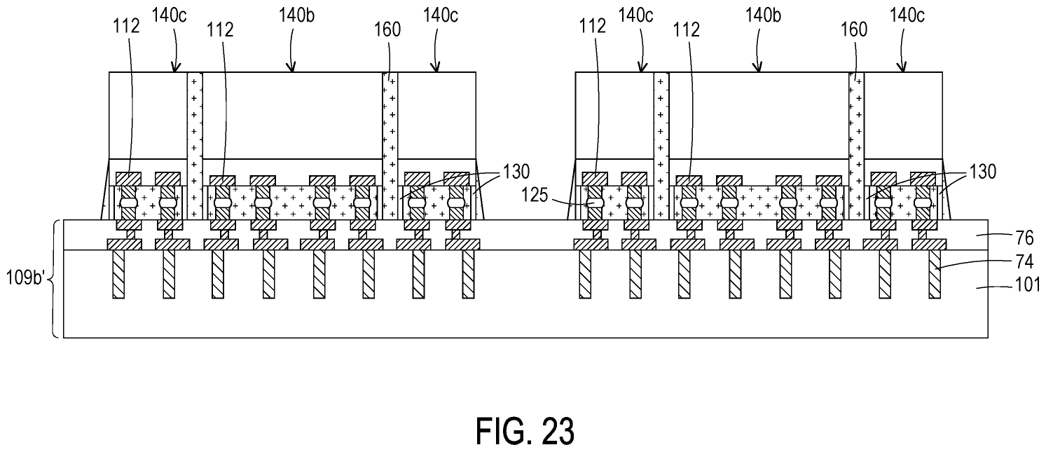

Referring to FIG. 23, after the bonding process, an underfill material 160 is dispensed into the gaps between the semiconductor devices 140a, 140b, and the redistribution structure 76. The underfill material 160 may extend up along sidewall of the semiconductor devices 140a, 140b. The underfill material 160 may be any acceptable material, such as a polymer, epoxy, molding underfill, or the like. The underfill material 160 may be formed by a capillary flow process after the semiconductor devices 140a, 140b are attached, or may be formed by a suitable deposition method before the semiconductor devices 140a, 140b are attached.

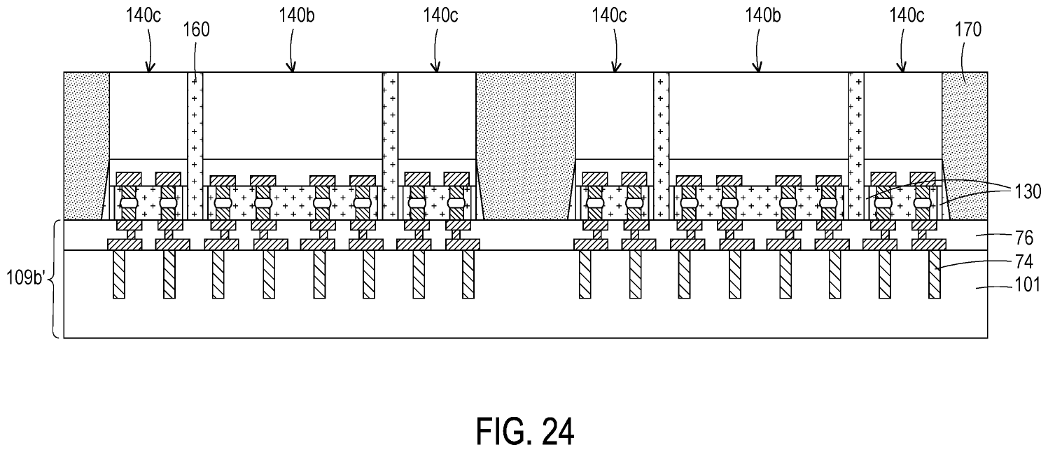

Referring to FIG. 24, an encapsulant 170 is formed over the semiconductor devices 140a, 140b and the semiconductor substrate 101. The encapsulant 170 may be a molding compound, epoxy, or the like, and may be applied by compression molding, transfer molding, or the like. A curing step is performed to cure the encapsulant 170, such as a thermal curing, an Ultra-Violet (UV) curing, or the like. In some embodiments, the semiconductor devices 140a, 140b are buried in the encapsulant 170, and after the curing of the encapsulant 170, a planarization step, such as a grinding, may be performed to remove excess portions of the encapsulant 170, which excess portions are over top surfaces of the semiconductor devices 140a, 140b. Accordingly, top surfaces of the semiconductor devices 140a, 140b are exposed, and are level with a top surface of the encapsulant 170.

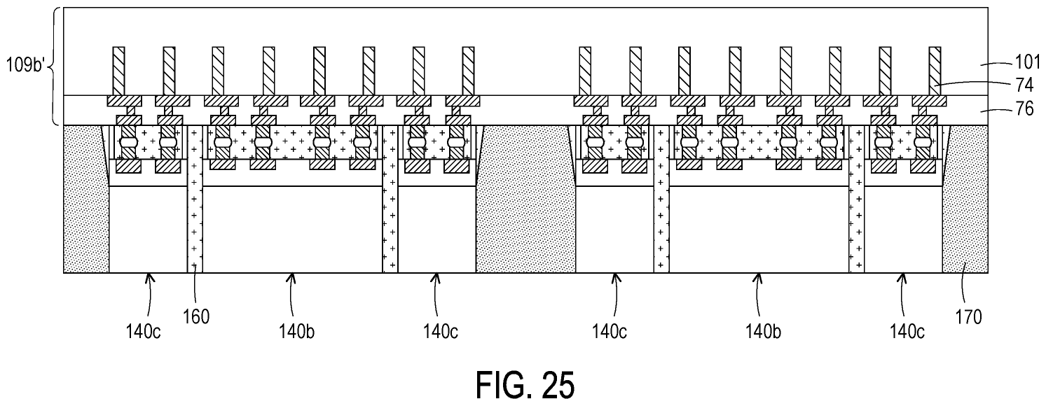

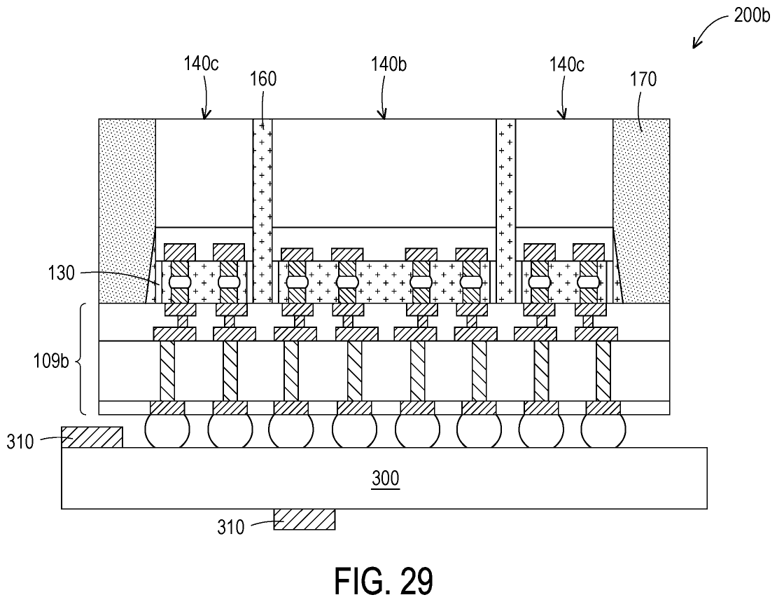

Referring to FIG. 25, the structure of FIG. 24 is then flipped over to prepare for the formation of the second side of the interposer, e.g., the interposer 109 shown in FIG. 29. Although not shown, the structure may be placed on carrier or support structure for the process of FIG. 25 through FIG. 27.

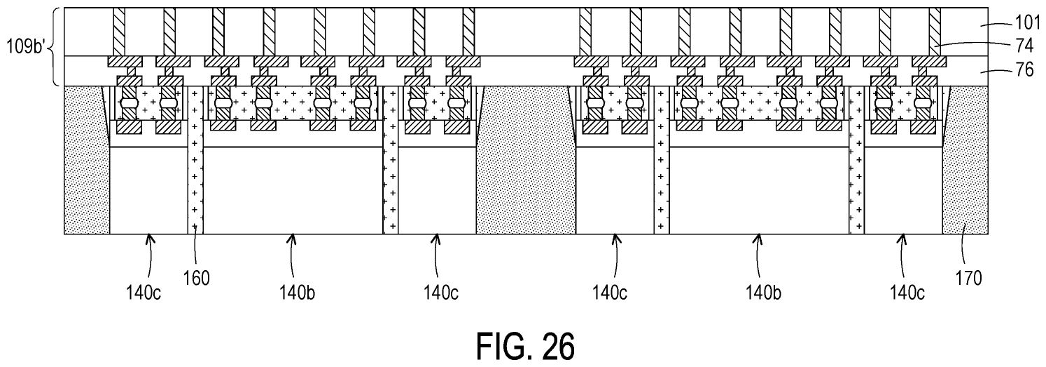

Then, referring to FIG. 26, a thinning process is performed on the second side of the semiconductor substrate 101 to thin the semiconductor substrate 101 until TVs 74 are exposed. The thinning process may include an etching process, a grinding process, the like, or a combination thereof.

In FIG. 24, a redistribution structure is formed on the semiconductor substrate 101, and is used to electrically connect the TVs 74 together and/or to external devices. The redistribution structure includes one or more dielectric layers 184 and metallization patterns 182 in the one or more dielectric layers 184. The metallization patterns may include vias and/or traces to interconnect TVs 74 together and/or to an external device. The metallization patterns 182 are sometimes referred to as Redistribution Lines (RDLs). The dielectric layers 184 may include silicon oxide, silicon nitride, silicon carbide, silicon oxynitride, low-K dielectric material, such as PSG, BPSG, FSG, SiOxCy, Spin-On-Glass, Spin-On-Polymers, silicon carbon material, compounds thereof, composites thereof, combinations thereof, or the like. The dielectric layers 184 may be deposited by any suitable method known in the art, such as spinning, CVD, PECVD, HDP-CVD, or the like. The metallization patterns 182 may be formed in the dielectric layer 184, for example, by using photolithography techniques to deposit and pattern a photoresist material on the dielectric layer 184 to expose portions of the dielectric layer 184 that are to become the metallization pattern 182. An etch process, such as an anisotropic dry etch process, may be used to create recesses and/or openings in the dielectric layer 184 corresponding to the exposed portions of the dielectric layer 184. The recesses and/or openings may be lined with a diffusion barrier layer and filled with a conductive material. The diffusion barrier layer may comprise one or more layers of TaN, Ta, TiN, Ti, CoW, or the like, deposited by ALD, or the like, and the conductive material may comprise copper, aluminum, tungsten, silver, and combinations thereof, or the like, deposited by CVD, PVD, plating, or the like. Any excessive diffusion barrier layer and/or conductive material on the dielectric layer may be removed, such as by using a CMP.

Then, a plurality of conductive bumps 180 are also formed the metallization patterns 182 and are electrically coupled to TVs 74. The conductive bumps 180 are formed at the top surface of the redistribution structure on the metallization patterns 182. In some embodiments, the metallization patterns 182 include UBMs. In the illustrated embodiment, the pads are formed in openings of the dielectric layers 184 of the redistribution structure. In another embodiment, the pads (UBMs) can extend through an opening of a dielectric layer 184 of the redistribution structure and also extend across the top surface of the redistribution structure.

In some embodiments, the conductive bumps 180 are solder balls and/or bumps, such as ball grid array (BGA) balls, C4, micro bumps, ENIG formed bumps, ENEPIG formed bumps, or the like. The conductive bumps 180 may include a conductive material such as solder, copper, aluminum, gold, nickel, silver, palladium, tin, the like, or a combination thereof. In some embodiments, the conductive bumps 180 are formed by initially forming a layer of solder through such commonly used methods such as evaporation, electroplating, printing, solder transfer, ball placement, or the like. Once a layer of solder has been formed on the structure, a reflow may be performed in order to shape the material into the desired bump shapes. In another embodiment, the conductive bumps 180 are metal pillars (such as a copper pillar) formed by a sputtering, printing, electro plating, electroless plating, CVD, or the like. The metal pillars may be solder free and have substantially vertical sidewalls. In some embodiments, a metal cap layer (not shown) is formed on the top of the metal pillar. The metal cap layer may include nickel, tin, tin-lead, gold, silver, palladium, indium, nickel-palladium-gold, nickel-gold, the like, or a combination thereof and may be formed by a plating process. The conductive bumps 180 may be used to bond to an additional electrical component, which may be a semiconductor substrate, a package substrate, a Printed Circuit Board (PCB), or the like (see 300 in FIG. 29).

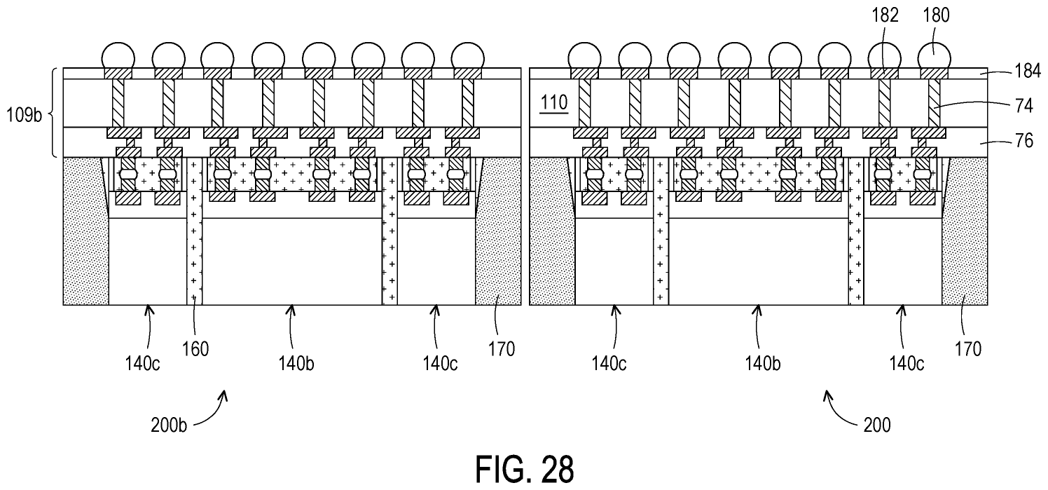

Referring to FIG. 28, the interposer 109 and the encapsulant 170 are singulated along scribe line regions to form a plurality of semiconductor packages 200. The singulation may be by sawing, dicing, or the like.

Then, FIG. 29 illustrates the attachment of a semiconductor package 200 on a substrate 300. The conductive bumps 180 are aligned to, and are put against, bond pads of the substrate 300. The conductive bumps 180 may be reflowed to create a bond between the substrate 300 and the semiconductor package 200. The substrate 300 may include a package substrate, such as a build-up substrate including a core therein, a laminate substrate including a plurality of laminated dielectric films, a PCB, or the like.

The substrate 300 may include electrical connectors (not shown), such as solder balls, opposite the component package to allow the substrate 300 to be mounted to another device. An underfill material (not shown) can be dispensed between the semiconductor package 200 and the substrate 300 and surrounding the conductive bumps 180. The underfill material may be any acceptable material, such as a polymer, epoxy, molding underfill, or the like. In one embodiment, the spacing pattern described above may be disposed on the semiconductor package 200 or the substrate 300 for maintaining a predetermined gap or spacing between semiconductor package 200 or the substrate 300 during the reflow process, so as to avoid bridging between two adjacent conductive bumps 180.

Based on the above discussions, it can be seen that the present disclosure offers various advantages. It is understood, however, that not all advantages are necessarily discussed herein, and other embodiments may offer different advantages, and that no particular advantage is required for all embodiments.

In accordance with some embodiments of the disclosure, a semiconductor package includes a first semiconductor substrate, a plurality of conductive bumps, a second semiconductor substrate, and a spacing pattern. The first semiconductor substrate includes a pad region and a plurality of first pads disposed within the pad region. The plurality of conductive bumps are disposed on the plurality of first pads respectively. The second semiconductor substrate is bonded to the first semiconductor substrate and includes a plurality of second pads bonded to the plurality of conductive bumps respectively. The spacing pattern is disposed between the first semiconductor substrate and the second semiconductor substrate, wherein the spacing pattern is located at a periphery of the pad region. In one embodiment, at least one of the plurality of conductive bumps includes a metal pillar and a solder cap disposed over the metal pillar, a height of the spacing pattern is substantially greater than a height of the metal pillar. In one embodiment, the spacing pattern includes a plurality of spacers at least disposed at a plurality of corners of the pad region. In one embodiment, the spacing pattern is in a continuous ring shape surrounding the periphery of the pad region. In one embodiment, the semiconductor package further includes a first passivation layer over the first semiconductor substrate and revealing the plurality of first pads and a second passivation layer over the second semiconductor substrate and revealing the plurality of second pads, wherein the spacing pattern is in contact with the first passivation layer and the second passivation layer. In one embodiment, a melting temperature a material of the spacing pattern is substantially equal to or greater than 200° C. In one embodiment, a material of the spacing pattern comprises copper (Cu), nickel (Ni), gold (Au), cobalt (Co), polyimide (PI), or benzocyclobutene (BCB). In one embodiment, the pad region includes a first region and a second region, wherein a first pitch between adjacent two of the plurality of first pads in the first region is smaller than a second pitch between adjacent two of the plurality of first pads in the second region, and the spacing pattern is disposed at a periphery of the first region.

In accordance with some embodiments of the disclosure, a semiconductor package includes a first semiconductor device, a second semiconductor device, a spacing pattern, and encapsulant. The first semiconductor substrate includes an array of first pads. The array of conductive bumps bonded between the array of first pads and the array of second pads. The second semiconductor substrate over the first semiconductor device and including an array of second pads. The spacing pattern is around the array of conductive bumps and leaning between the first semiconductor device and the second semiconductor device. The encapsulant encapsulates at least one of the first semiconductor device and the second semiconductor device. In one embodiment, the semiconductor package further includes a redistribution structure formed over the encapsulant and the at least one of the first semiconductor device and the second semiconductor device. In one embodiment, the encapsulant is formed over a top surface of the second semiconductor device and encapsulates the first semiconductor device. In one embodiment, each of the array of conductive bumps comprises a metal pillar and a solder cap disposed over the metal pillar, a height of the spacing pattern is substantially greater than a height of the metal pillar. In one embodiment, the spacing pattern is located at a periphery of a pad region where the array of first pads is disposed. In one embodiment, a melting temperature a material of the spacing pattern is substantially equal to or greater than 200° C. In one embodiment, a material of the spacing pattern comprises copper (Cu), nickel (Ni), gold (Au), cobalt (Co), polyimide (PI), or benzocyclobutene (BCB). In one embodiment, a pad region where the array of first pads are disposed includes a first region and a second region, wherein a first pitch between any adjacent two of the array of first pads in the first region is smaller than a second pitch between any adjacent two of the array of first pads in the second region, and the spacing pattern is disposed at a periphery of the first region.

In accordance with some embodiments of the disclosure, a manufacturing method of a semiconductor package includes the following steps. A first semiconductor substrate including an array of first pads is provided; an array of conductive bumps is formed on the array of first pads respectively; a spacing pattern is formed over the first semiconductor substrate; the first semiconductor substrate is placed over a second semiconductor substrate, wherein the second semiconductor substrate includes an array of second pads corresponding to the array of conductive bumps respectively; and the second semiconductor substrate and the first semiconductor substrate are bonded by performing a reflow process, wherein the spacing pattern is in contact with the first semiconductor substrate and the second semiconductor substrate during the reflow process. In one embodiment, the manufacturing method of the semiconductor package further includes: forming a first passivation layer over the first semiconductor substrate, wherein the first passivation layer at least partially reveals the array of first pads. In one embodiment, the spacing pattern is formed on the first passivation layer after the array of conductive bumps is formed. In one embodiment, a melting temperature a material of the spacing pattern is substantially greater than a process temperature of the reflow process.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a first semiconductor substrate comprising a pad region and a plurality of first pads disposed within the pad region;
a plurality of conductive bumps disposed on the plurality of first pads respectively;
a second semiconductor substrate bonded to the first semiconductor substrate and comprising a plurality of second pads bonded to the plurality of conductive bumps respectively; and
a spacing pattern disposed between the first semiconductor substrate and the second semiconductor substrate, wherein the spacing pattern is located at a periphery of the pad region.

2. The semiconductor package as claimed in claim 1, wherein at least one of the plurality of conductive bumps comprises a metal pillar and a solder cap disposed over the metal pillar, a height of the spacing pattern is substantially greater than a height of the metal pillar.

3. The semiconductor package as claimed in claim 1, wherein the spacing pattern comprises a plurality of spacers at least disposed at a plurality of corners of the pad region.

4. The semiconductor package as claimed in claim 1, wherein the spacing pattern is in a continuous ring shape surrounding the periphery of the pad region.

5. The semiconductor package as claimed in claim 1, further comprising a first passivation layer over the first semiconductor substrate and revealing the plurality of first pads and a second passivation layer over the second semiconductor substrate and revealing the plurality of second pads, wherein the spacing pattern is in contact with the first passivation layer and the second passivation layer.

6. The semiconductor package as claimed in claim 1, wherein a melting temperature a material of the spacing pattern is substantially equal to or greater than 200° C.

7. The semiconductor package as claimed in claim 1, wherein a material of the spacing pattern comprises copper (Cu), nickel (Ni), gold (Au), cobalt (Co), polyimide (PI), or benzocyclobutene (BCB).

8. The semiconductor package as claimed in claim 1, wherein the pad region comprises a first region and a second region, wherein a first pitch between adjacent two of the plurality of first pads in the first region is smaller than a second pitch between adjacent two of the plurality of first pads in the second region, and the spacing pattern is disposed at a periphery of the first region.

9. A semiconductor package, comprising:
a first semiconductor device comprising an array of first pads;
a second semiconductor device over the first semiconductor device and comprising an array of second pads;
an array of conductive bumps bonded between the array of first pads and the array of second pads;
a spacing pattern disposed around the array of conductive bumps and leaning between the first semiconductor device and the second semiconductor device; and
an encapsulant encapsulating at least one of the first semiconductor device and the second semiconductor device.

10. The semiconductor package as claimed in claim 9, further comprising a redistribution structure formed over the encapsulant and the at least one of the first semiconductor device and the second semiconductor device.

11. The semiconductor package as claimed in claim 9, wherein the encapsulant is formed over a top surface of the second semiconductor device and encapsulates the first semiconductor device.

12. The semiconductor package as claimed in claim 9, wherein each of the array of conductive bumps comprises a metal pillar and a solder cap disposed over the metal pillar, a height of the spacing pattern is substantially greater than a height of the metal pillar.

13. The semiconductor package as claimed in claim 9, wherein the spacing pattern is located at a periphery of a pad region where the array of first pads is disposed.

14. The semiconductor package as claimed in claim 9, wherein a melting temperature a material of the spacing pattern is substantially equal to or greater than 200° C.

15. The semiconductor package as claimed in claim 9, wherein a material of the spacing pattern comprises copper (Cu), nickel (Ni), gold (Au), cobalt (Co), polyimide (PI), or benzocyclobutene (BCB).

16. The semiconductor package as claimed in claim 9, wherein a pad region where the array of first pads are disposed comprises a first region and a second region, wherein a first pitch between any adjacent two of the array of first pads in the first region is smaller than a second pitch between any adjacent two of the array of first pads in the second region, and the spacing pattern is disposed at a periphery of the first region.

17. A manufacturing method of a semiconductor package, comprising:
providing a first semiconductor substrate comprising an array of first pads;
forming an array of conductive bumps on the array of first pads respectively;
forming a spacing pattern over the first semiconductor substrate;
placing the first semiconductor substrate over a second semiconductor substrate, wherein the second semiconductor substrate comprises an array of second pads corresponding to the array of conductive bumps respectively; and
bonding the second semiconductor substrate and the first semiconductor substrate by performing a reflow process, wherein the spacing pattern is in contact with the first semiconductor substrate and the second semiconductor substrate during the reflow process.

18. The manufacturing method of the semiconductor package as claimed in claim 17, further comprising:
forming a first passivation layer over the first semiconductor substrate, wherein the first passivation layer at least partially reveals the array of first pads.

19. The manufacturing method of the semiconductor package as claimed in claim 18, wherein the spacing pattern is formed on the first passivation layer after the array of conductive bumps is formed.

20. The manufacturing method of the semiconductor package as claimed in claim 18, wherein a melting temperature a material of the spacing pattern is substantially greater than a process temperature of the reflow process.
